(19) United States
(12) Patent Application Publication
(10) Pub. No.: US 2024/0203889 A1
(43) Pub. Date: Jun. 20, 2024

(54) SUBSTRATE AND PACKAGE STRUCTURE

(71) Applicant: CHENGDU BRIGHT POWER SEMICONDUCTOR CO., LTD., Sichuan Free Trade Pilot Zone (CN)

(72) Inventors: Tiecheng ZHANG, Sichuan Free Trade Pilot Zone (CN); Hujun ZHANG, Sichuan Free Trade Pilot Zone (CN); Dong LI, Sichuan Free Trade Pilot Zone (CN); Qian OUYANG, Sichuan Free Trade Pilot Zone (CN)

(21) Appl. No.: 18/535,266

(22) Filed: Dec. 11, 2023

(30) Foreign Application Priority Data
Dec. 20, 2022 (CN) 202223418187.6

(51) Int. Cl. H01L 23/538; H01L 23/00

(52) U.S. Cl. CPC H01L 23/5383; H01L 23/5386; H01L 24/16; H01L 2224/16227

(57) ABSTRACT

A substrate is disclosed, the substrate includes a plurality of electrically interconnected metal layers sequentially stacked from the top downward and dielectric layers interposed between the metal layers. The substrate has a low-side power connection region where metal strips in at least one of the metal layers extend in a direction different from a direction of extension of metal strips in another one of the metal layers extend. This enables a package structure incorporating the substrate to have a good stress distribution, which guarantees reliability required by long-term use. Also provided is a package structure including the substrate and a semiconductor die flipped and mounted on the substrate.

### CROSS-REFERENCES TO RELATED APPLICATION

This application claims the priority of Chinese patent application number 202223418187.6, filed on Dec. 20, 2022, the entire contents of which are incorporated herein by reference.

### TECHNICAL FIELD

This disclosure relates to the field of packaging technology and, in particular, to a substrate and a package structure.

### BACKGROUND

Quad flat no-lead (QFN) packages are square or rectangular leadless surface-mount packages with a large exposed center pad on the bottom for thermal conduction and peripheral conductive pads surrounding the large pad for electrical connection.

FIG. 1 is a schematic cross-sectional view of a conventional QFN package structure. As shown in FIG. 1, in the QFN package structure, a chip 101 is flipped and mounted on a frame 102, and solder bumps 101a on the chip are soldered to lead contacts 102a of the frame. A plastic encapsulation material 103 encapsulates the chip 101 and is filled between the lead terminals 102a. In the QFN package structure, as indicated by the dashed ellipse in FIG. 1, the portions between the lead terminals 102a are supported only by the plastic encapsulation material and lack support from any metal layer. This makes them extremely prone to the formation of defects under stress and exposes the entire package structure to the risk of folding and breakage. Thus, the package structure has poor reliability.

Therefore, there is a need to improve the reliability of such package structures.

### SUMMARY OF THE INVENTION

This disclosure provides a substrate and a package structure with improved reliability and electrical performance.

To this end, in one aspect of this disclosure, there is provided a substrate including a plurality of electrically interconnected metal layers sequentially stacked from the top downward and dielectric layers interposed between the metal layers, the substrate having a low-side power connection region where metal strips in at least one of the metal layers extend in a direction different from a direction of extension of metal strips in another one of the metal layers extend.

Optionally, for each direction of extension, there may be at least two of the metal layers, in which the metal strips extend in the specific direction of extension.

Optionally, the metal strips in any adjacent two of the metal layers may extend in different directions.

Optionally, the low-side power connection region may be aligned in position with a low-side power MOS region of the semiconductor die, wherein bumps in the low-side power MOS region are connected to metal strips in a topmost one of the metal layers in the low-side power connection region.

Optionally, a plurality of metal strips may be arranged in the topmost metal layer in the low-side power connection region, wherein bumps in each single column in the low-side power MOS region of the semiconductor die are connected to a single one of the metal strips in the topmost metal layer.

Optionally, columns of bumps in the low-side power MOS region electrically connected to any respective adjacent two of the metal strips in the topmost metal layer in the low-side power connection region may belong to different functional networks.

Optionally, the substrate may include a first metal layer, a second metal layer, a third metal layer and a fourth metal layer, which are sequentially stacked from the top downward and electrically interconnected, wherein in the low-side power connection region, the metal strips in two of the first, second, third and fourth metal layers extend in a first direction, and the metal strips in the remaining two metal layers extend in a second direction different from the first direction.

Optionally, the first direction may be perpendicular to the second direction.

Optionally, the direction of extension of the metal strips in the first metal layer may be same to the direction a plurality of columns of bumps extend.

Optionally, the substrate may include a solder mask on a surface thereof close to the fourth metal layer, the solder mask provided therein with a plurality of elongated openings, in which the fourth metal layer is partially exposed, wherein in the low-side power connection region, the direction of extension of the metal strips in the fourth metal layer is the same as a direction of extension of the elongated openings.

Optionally, in the low-side power connection region, the metal strips in the first metal layer may extend in the first direction, the metal strips in the second metal layer may extend in the second direction, the metal strips in the third metal layer may extend in the first direction, and the metal strips in the fourth metal layer may extend in the second direction.

In another aspect of the disclosure, there is provided a package structure including the substrate as defined above and a semiconductor die flipped and mounted on the substrate.

Optionally, a front side of the semiconductor die may face toward the substrate and be provided thereon with a plurality of bumps, wherein the semiconductor die has a low-side power MOS region, which is aligned in position with the low-side power connection region and provided therein with bumps connected to the metal strips in the topmost metal layer in the substrate in the low-side power connection region.

Optionally, the bumps in the low-side power MOS region of the semiconductor die may be arranged into a plurality of columns, wherein bumps of each single one of the columns belong to the same functional network, and wherein bumps of any adjacent two of the columns belong to different functional networks.

Optionally, the semiconductor die may also have a high-side power MOS region and a control circuit region, wherein bumps in the high-side and low-side power MOS regions have the same cross-sectional shape, which is different from a cross-sectional shape of bumps in the control circuit region.

This disclosure provides a substrate including a plurality of electrically interconnected metal layers sequentially stacked from the top downward and dielectric layers interposed between the metal layers. The substrate has a low-side power connection region where metal strips in at least one of the metal layers extend in a direction different from a direction of extension of metal strips in another one of the metal layers extend. This enables a package structure incorporating the substrate to have a good stress distribution, which guarantees reliability required by long-term use.

Further, metal strips in at least one of the metal layers extend in a direction different from a direction of extension of metal strips in another one of the metal layers extend, and for each direction of extension, there may be at least two of the metal layers, in which the metal strips extend in the specific direction of extension. This ensures there are at least two metal layers connected in parallel in each direction of extension, thereby ensuring high current conduction capability of the metal layers in the substrate, reducing parasitic resistance and inductance of the package structure and improving its electrical performance.

### BRIEF DESCRIPTION OF THE DRAWINGS

In order to better describe and illustrate embodiments and/or examples of any utility models presented within this disclosure, reference may be made to one or more accompanying drawings. The additional details or examples used to describe the accompanying drawings should not be considered as limitations to the scope of any of the disclosed utility models, any of the presently described embodiments and/or examples, or the presently understood best mode of any invention presented within this disclosure.

FIG. 1 is a schematic cross-sectional view of a conventional QFN package structure.

FIG. 2 is a schematic cross-sectional view of a package structure according to an embodiment of the disclosure.

FIG. 3 is a schematic layout diagram of a front side of a semiconductor die according to an embodiment of the disclosure.

FIGS. 4a to 4d are schematic plan views of four metal layers in a substrate according to an embodiment of the disclosure.

FIGS. 5a to 5d are schematic plan views of the four metal layers in an example of the substrate.

FIG. 6 is a schematic layout diagram of a front side of a semiconductor die according to an embodiment of the disclosure.

FIGS. 7a to 7d are schematic plan views of four metal layers in a substrate according to an embodiment of the disclosure.

FIGS. 8a to 8d are schematic plan views of four metal layers in a substrate according to an embodiment of the disclosure.

FIG. 9 schematically illustrates a bottom surface of a substrate according to an embodiment of the disclosure.

### REFERENCE NUMERALS IN DRAWINGS

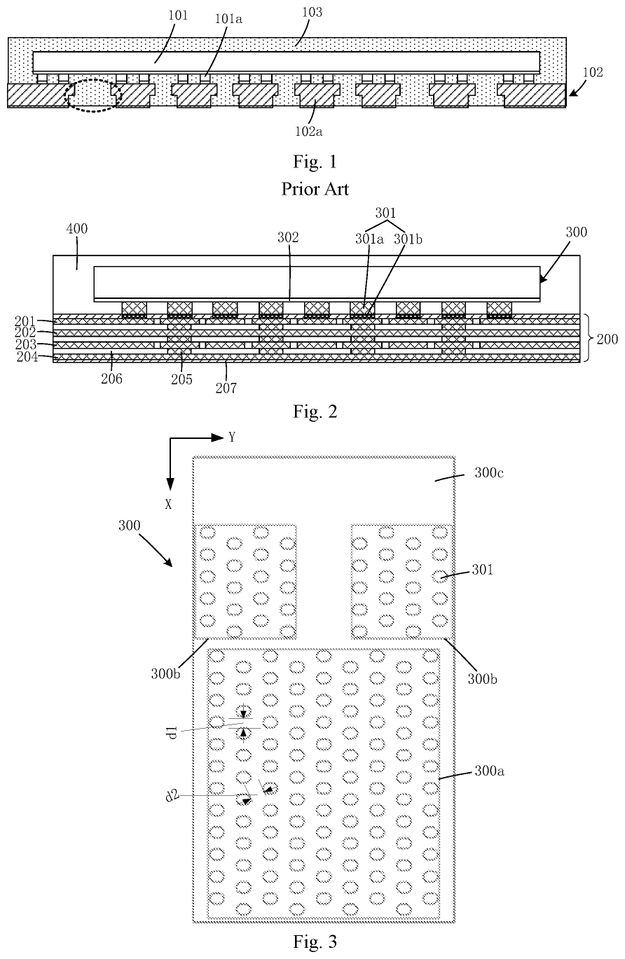

FIG. 1: 101—chip; 101a—solder bump; 102—frame; 102a—lead terminal; 103—plastic encapsulation material;

FIGS. 2-9: 200—substrate; 200a—metal strip; 201—first metal layer; 202—second metal layer; 203—third metal layer; 204—fourth metal layer; 205—conductive via; 206—dielectric layer; 207—solder mask; 208—elongated opening; 300—semiconductor die; 300a—low-side power MOS region; 300b—high-side power MOS region; 300c—control circuit region; 301—bump; 301a—bump portion; 301b—solder portion; 302—rewiring layer; 400—plastic encapsulation layer.

### DETAILED DESCRIPTION

The present disclosure will be described in greater detail below with reference to the accompanying drawings and specific embodiments. From the following description, advantages and features of this disclosure will become more apparent. Note that the figures are provided in a very simplified form not necessarily drawn to exact scale and only for the sake of easier and clearer description of the embodiments disclosed herein.

The present application provides a substrate including a plurality of electrically interconnected metal layers, which are sequentially stacked from the top downward and spaced apart by dielectric layers therebetween. The substrate has a low-side power connection region, in which metal strips in at least one of the metal layers extend in a different direction from strips in another one of the metal layers. This enables a package structure incorporating the substrate to have a good stress distribution, which guarantees reliability required by long-term use.

For each direction of extension, there are at least two of the metal layers, in which metal strips extend in the specific direction of extension. This ensures there are at least two metal layers connected in parallel in each direction of extension, thereby ensuring high current conduction capability of the metal layers in the substrate, reducing parasitic resistance and inductance of the package structure and improving its electrical performance.

FIG. 2 is a schematic cross-sectional view of a package structure according to an embodiment of the disclosure. For example, as shown in FIG. 2, a substrate 200 in the package structure includes a first metal layer 201, a second metal layer 202, a third metal layer 203 and a fourth metal layer 204, which are sequentially stacked from the top downward and interconnected. Each of the metal layer includes a plurality of metal strips. In a low-side power connection region of the substrate, the metal strips in two metal layers of the first metal layer 201, the second metal layer 202, the third metal layer 203 and the fourth metal layer 204 extend in a first direction, and the metal strips in the remaining two metal layers extend in a second direction, which is different from the first direction. The first and second directions may be perpendicular to each other.

Each of the first metal layer 201, the second metal layer 202, the third metal layer 203 and the fourth metal layer 204 may be made of a material including copper. The metal strips may be copper sheets. All the first metal layer 201, the second metal layer 202, the third metal layer 203 and the fourth metal layer 204 may be formed using an electroplating process.

As shown in FIG. 2, dielectric layers 206 are interposed between adjacent metal layers in the substrate 200, and via holes are formed through the dielectric layers 206. Conductive via 205 may be formed in the via holes to electrically interconnect the metal layers. Exemplary materials for the dielectric layers 206 may include, but are not limited to, epoxy resins.

In order to protect the metal layers against oxidation and thus reduce the risk of short circuits, solder masks 207 may be formed respectively on top and bottom surfaces of the substrate 200. Openings may be formed in the solder masks 207, in which surfaces of the first metal layer 201 and the fourth metal layer 204 are partially exposed. The solder masks 207 may be formed of a material including a solder resist ink.

As shown in FIG. 2, a semiconductor die 300 is mounted on the substrate 200, optionally, the front side of the semiconductor die 300 faces the substrate 200. Without limitation, the semiconductor die 300 may form a power management chip. A rewiring layer 302 may be provided on the front side of the semiconductor die 300. The rewiring layer 302 may be formed of a material including copper. Without limitation, the rewiring layer 302 may have a thickness of 10 μm.

A plurality of bumps 301 may be provided on the front side of the semiconductor die 300. The plurality of bumps 301 may be connected to the first metal layer 201 in the substrate 300. In this embodiment, the first metal layer 201 is the topmost metal layer, and the fourth metal layer 204 is the bottommost metal layer.

Referring to FIG. 2, each bump 301 may include a bump portion 301a and a solder portion 301b on an end face of the bump portion 301a away from the semiconductor die 300. The bump portion 301a may be shaped like a post. Without limitation, the bump portion 301a may be formed of a material including copper. The bump portion 301a may have a height of 80 μm to 90 μm. The solder portion 301b may be formed of tin, a tin alloy or another alloy. As non-limiting examples, when made of pure tin, the solder portion 301b may have a thickness of 7 μm to 20 μm; when made of NiPdAu, the solder portion 301b may have a thickness of 2 μm to 3 μm; and when made of a SnAg alloy, the solder portion 301b may have a thickness of 25 μm to 35 μm.

It is to be noted that, according to the present application, compared with the use of conventional bond wires of a lead frame, connecting the semiconductor die 300 to the substrate 200 via the bumps 301 on the front side can create shorter and cross-sectionally larger vertical current signal paths, which help reduce parasitic and parasitic resistance of the product and significantly improve its electrical performance.

FIG. 3 shows a schematic layout diagram of the front side of the semiconductor die according to an embodiment of the disclosure. With combined reference to FIGS. 2 and 3, the semiconductor die 300 has a low-side power MOS region 300a aligned in position with a low-side power connection region of the substrate 300. Bumps 301 in the low-side power MOS region 300a are connected to metal strips in the topmost metal layer in the substrate 200 (i.e., the first metal layer 201) in the low-side power connection region.

As shown in FIG. 3, the semiconductor die 300 also has a high-side power MOS regions 300b. Optionally, without limitation, it may have two high-side power MOS regions 300b. Each high-side power MOS regions 300b may have an area smaller than that of the low-side power MOS region 300a. The semiconductor die 300 also has a control circuit region 300c, in which a control circuit is arranged to control operation of the low-side power MOS region 300a and the high-side power MOS regions 300b.

For example, as shown in FIG. 3, without limitation, the low-side power MOS region 300a may be located in one half of the semiconductor die 300, and the high-side power MOS regions 300b may be located in the other half of the semiconductor die 300 at the side thereof proximal to the low-side power MOS region 300a. The control circuit region 300c may be arranged on the side of the high-side power MOS regions 300b distal from the low-side power MOS region 300a and between the high-side power MOS regions 300b and the low-side power MOS region 300a.

In each of the low-side power MOS region 300a and the high-side power MOS regions 300b of the semiconductor die 300, a plurality of bumps 301 are arranged into an array. Bumps 301 in each single column belong to the same functional network, and bumps 301 in any adjacent two columns belong to different functional networks. In FIG. 3, the columns define an X direction. Alternating bumps 301 belonging to different functional networks in the low-side power MOS region 300a and the high-side power MOS regions 300b is helpful in improving the product's electrical performance.

Referring to FIG. 3, in the low-side power MOS region 300a and the high-side power MOS regions 300b, bumps 301a in each column may be spaced at a pitch d1 of 90 μm to 130 μm, e.g., the pitch d1 is 110 μm, and a minimum pitch d2 between bumps 301 in any adjacent two columns may range from 120 μm to 160 μm, e.g., pitch d2 is 140 μm, without limitation.

In this embodiment, the bumps 301 in the high-side power MOS regions 300b and the low-side power MOS region 300a all have the same cross-sectional shape, which, however, is different from a cross-sectional shape of bumps (not shown) in the control circuit region 300c.

For example, as shown in FIG. 3, the bumps 301 in the high-side power MOS regions 300b and the low-side power MOS region 300a may all have an elliptic cross-section, while the bumps (not shown) in the control circuit region 300c may all have a circular cross-section. This allows the bumps in the MOS regions to have a maximum possible total cross-sectional area, which can maximize a total current through the bumps. In addition, in order to allow more bumps 301 to be arranged per unit area, the minor axis of the cross-section of the bumps 301 in the low-side power MOS region 300a may be oriented in the direction defined by the columns. The major axis of the ellipses may range from 94 μm to 176 μm, and the minor axis thereof may range from 70 μm to 130 μm. The circular cross-section may have a diameter of 70 μm to 130 μm. In this way, issues that may arise from the different bump sizes during reflow soldering for surface mounting of the die can be mitigated as much as possible.

Continuing the example, in which the substrate 200 includes four metal layers, in order to achieve higher current conduction capability of the four metal layers in the substrate 200, according to this application, the metal strips in two of the four metal layers may extend in the first direction, and the metal strips in the remaining two metal layers may extend in the second direction, the first direction is perpendicular to the second direction.

The direction of extension of the metal strips in the first metal layer 201 in the low-side power connection region of the substrate 200 is defined by the direction of extension of the columns of bumps in the low-side power MOS region 300a of the semiconductor die 300. In other words, the direction of extension of the metal strips in the first metal layer 201 in the low-side power connection region is the same as the direction defined by the columns of bumps in the low-side power MOS region 300a of the semiconductor die 300.

FIG. 9 schematically illustrates the bottom surface of the substrate according to an embodiment of the disclosure. As shown in FIGS. 2 and 9, one of the solder masks 207 is provided on the surface of the substrate 200 near the fourth metal layer 204, and a plurality of elongated openings 208 may be formed in the solder mask 207, in which the fourth metal layer 204 is partially exposed. Moreover, in the low-side power connection region, the elongated openings 208 may extend in the same direction as the metal strips in the fourth metal layer 204.

The two metal layers situated between the first metal layer 201 and the fourth metal layer 204 may be flexibly configured according to the design of the first metal layer 201 and the fourth metal layer 204.

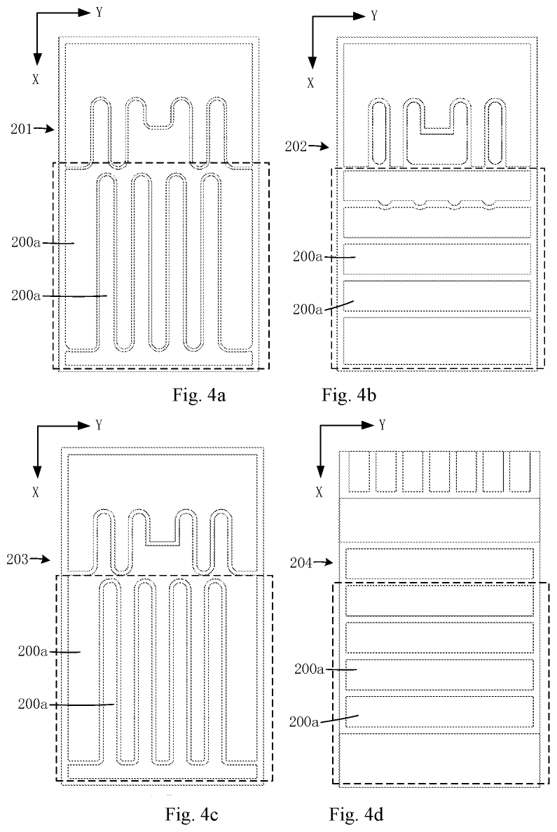

FIGS. 4a to 4d are schematic plan views of the four metal layers in the substrate according to an embodiment of the disclosure. The dashed boxes in FIGS. 4a to 4d indicate the location of the low-side power connection region. As shown in FIGS. 4a to 4d, each of the first metal layer 201, the second metal layer 202, the third metal layer 203 and the fourth metal layer 204 has a plurality of metal strips 200a in the low-side power connection region.

The metal strips may be rectangular, oblong or otherwise elongate in shape, without limitation. The metal strips in each metal layer may have the same or different shapes, but must extend in the same direction. The metal strips in different metal layers may have the same or different shapes. Adjacent metal strips may be isolated by isolation trenches.

As shown in FIG. 3, in one embodiment where the bumps 301 in each single column in the low-side power MOS region 300a belong to the same functional network, i.e., the bumps 301 in the same functional network are arranged in the low-side power MOS region 300a longitudinally (i.e., in the X direction), in the low-side power connection region of the substrate 200, the metal strip 200a in the first metal layer 201 extend in the first direction (i.e., the X direction), as shown in FIG. 4a, the metal strip 200a in the second metal layer 202 in the second direction (a Y direction), as shown in FIG. 4b, the metal strip 200a in the third metal layer 203 in the first direction, as shown in FIG. 4c, and the metal strip 200a in the fourth metal layer 204 in the second direction, as shown in FIG. 4d.

Specifically, as shown in FIG. 4a, in the low-side power connection region, the metal strips 200a in the first metal layer 201 are juxtaposed in the Y direction; as shown in FIG. 4b, in the low-side power connection region, the metal strips 200a in the second metal layer 202 are juxtaposed in the X direction; as shown in FIG. 4c, in the low-side power connection region, the metal strips 200a in the third metal layer 203 are juxtaposed in the Y direction; and as shown in FIG. 4d, in the low-side power connection region, the metal strips 200a in the fourth metal layer 204 are juxtaposed in the X direction.

It is to be noted that, according to the present application, in the low-side power MOS region 300a of the semiconductor die 300, the bumps 301 in each column are connected to a single one of the metal strips 200a in the first metal layer 201 in the low-side power connection region. Moreover, columns of bumps in the low-side power MOS region of the semiconductor die 300 electrically connected to any respective adjacent two metal strips in the topmost metal layer (i.e., the first metal layer 201) in the low-side power connection region belong to different functional networks.

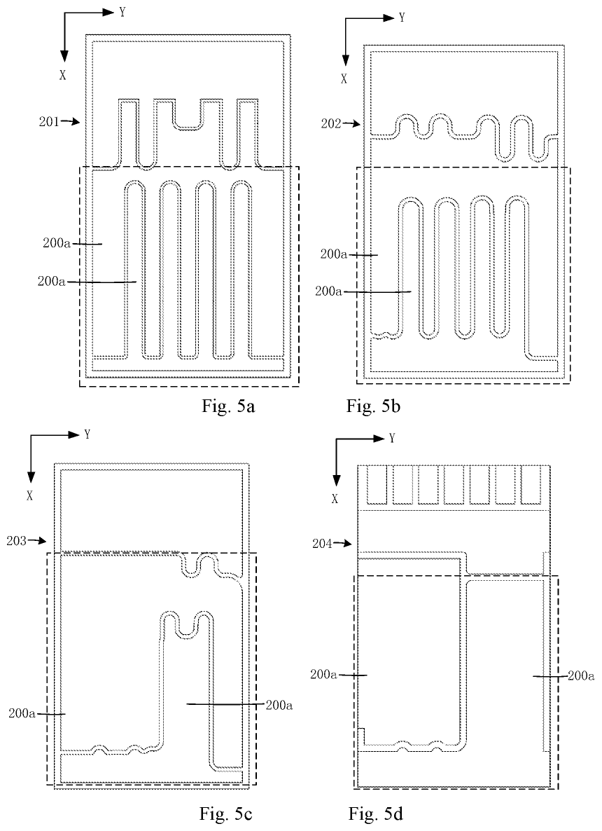

FIGS. 5a to 5d are schematic plan views of the four metal layers of an example of the substrate. The dashed boxes in FIGS. 5a to 5d indicate the location of the low-side power connection region. Assuming the bumps are arranged as shown in FIG. 3 as an example, in the low-side power connection region, the metal strip 200a in the first metal layer 201 extend in the X direction and juxtaposed in the Y direction, as shown in FIG. 5a; the metal strip 200a in the second metal layer 202 extend in the X direction and juxtaposed in the Y direction, as shown in FIG. 5b; the metal strip 200a in the third metal layer 203 extend in the X direction and juxtaposed in the Y direction, as shown in FIG. 5c; and the metal strip 200a in the fourth metal layer 204 extend in the X direction and juxtaposed in the Y direction, as shown in FIG. 5d. In other words, in the low-side power connection region, as shown in FIGS. 5a to 5d, the metal strips in each of the four metal layers extend longitudinally. Simulation data show that the design shown in FIGS. 4a to 4d, in which the metal strips in two of the four metal layers in the substrate 200 extend longitudinally and the metal strips in the remaining two metal layers extend transversely, imparts better electrical performance to the package structure, compared with the design shown in FIGS. 5a to 5d, in which the metal strips in all the four metal layers in the substrate 200 extend longitudinally.

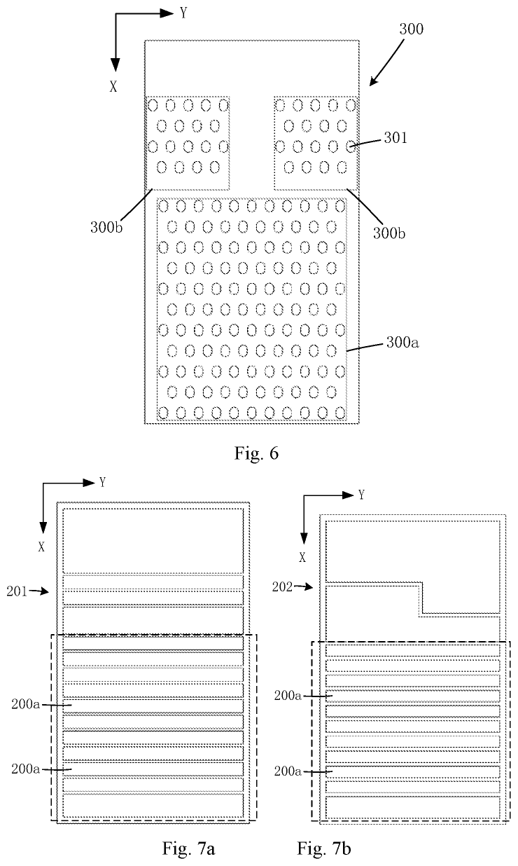

FIG. 6 is a schematic layout diagram of the front side of the semiconductor die according to an embodiment of the disclosure. Referring to FIG. 6, in the low-side power MOS region 300a and the high-side power MOS regions 300b of the semiconductor die 300, the bumps 301 in each single column belong to the same functional network, and the bumps 301 in adjacent two columns belong to different functional networks. In FIG. 6, the Y direction is defined by rows. In this embodiment, the bumps 301 in the low-side power MOS region 300a in each single functional network are arranged transversely.

FIGS. 7a to 7d are schematic plan views of the four metal layers in the substrate according to an embodiment of the disclosure. The dashed boxes in FIGS. 7a to 7d indicate the location of the low-side power connection region. In one embodiment where the bumps 301 of each single functional network are transversely arranged in the low-side power MOS region 300a of the semiconductor die 300, as shown in FIG. 6, the metal strips 200a in the first metal layer 201 extend in the second direction (i.e., the Y direction) as shown in FIG. 7a, the metal strips 200a in the second metal layer 202 in the second direction as shown in FIG. 7b, the metal strips 200a in the third metal layer 203 in the first direction (i.e., the X direction) as shown in FIG. 7c and the metal strips 200a in the fourth metal layer 204 in the first direction as shown in FIG. 7d, in the low-side power MOS region 300a of the semiconductor die 300.

Specifically, as shown in FIG. 7a, in the low-side power connection region, the metal strips 200a in the first metal layer 201 are juxtaposed in the X direction; as shown in FIG. 7b, in the low-side power connection region, the metal strips 200a in the second metal layer 202 are juxtaposed in the X direction; as shown in FIG. 7c, in the low-side power connection region, the metal strips 200a in the third metal layer 203 are juxtaposed in the Y direction; and as shown in FIG. 7d, in the low-side power connection region, the metal strips 200a in the fourth metal layer 204 are juxtaposed in the Y direction.

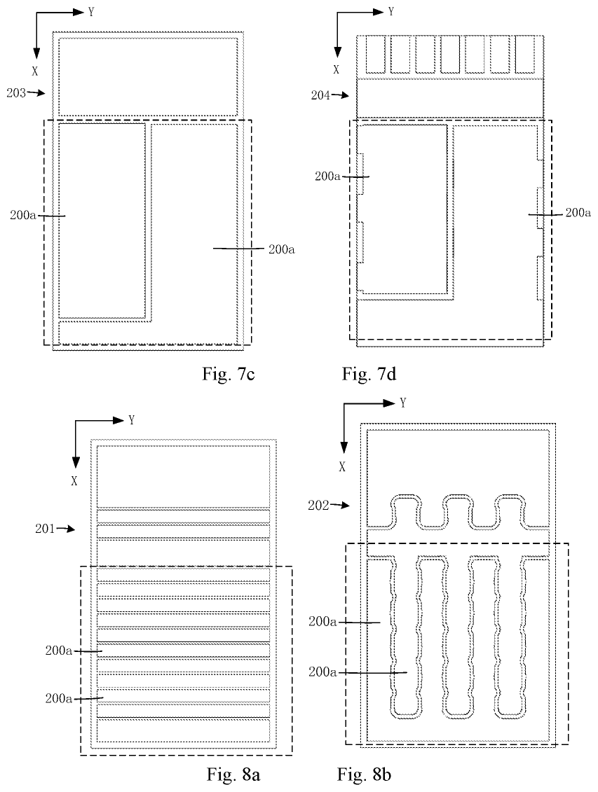

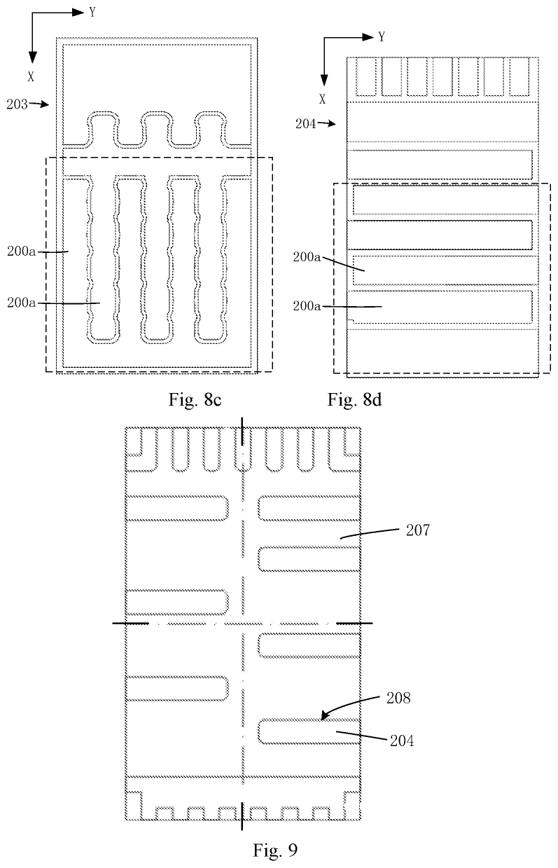

FIGS. 8a to 8d are schematic plan views of the four metal layers of an example of the substrate according to an embodiment of the disclosure. The dashed boxes in FIGS. 8a to 8d indicate the location of the low-side power connection region. In one embodiment where the bumps 301 of each single functional network are transversely arranged in the low-side power MOS region 300a of the semiconductor die 300, as shown in FIG. 6, the metal strips 200a in the first metal layer 201 extend in the second direction (i.e., the Y direction) as shown in FIG. 8a, the metal strips 200a in the second metal layer 202 in the first direction (i.e., the X direction) as shown in FIG. 8b, the metal strips 200a in the third metal layer 203 in the first direction as shown in FIG. 8c and the metal strips 200a in the fourth metal layer 204 in the second direction as shown in FIG. 8d, in the low-side power MOS region 300a of the semiconductor die 300.

Specifically, as shown in FIG. 8a, in the low-side power connection region, the metal strips 200a in the first metal layer 201 are juxtaposed in the X direction; as shown in FIG. 8b, in the low-side power connection region, the metal strips 200a in the second metal layer 202 are juxtaposed in the Y direction; as shown in FIG. 8c, in the low-side power connection region, the metal strips 200a in the third metal layer 203 are juxtaposed in the Y direction; and as shown in FIG. 8d, in the low-side power connection region, the metal strips 200a in the fourth metal layer 204 are juxtaposed in the X direction.

In one embodiment, the metal strips in any adjacent two of the metal layers extend in different directions. This design allows the package structure to have better electrical performance.

Simulation data show that, for the arrangement in which the bumps 301 in each single functional network being arranged longitudinally (i.e., the X direction) in the low-side power MOS region 300a, the design of the substrate 200 shown in FIGS. 4a to 4d enables the package structure to have better electrical performance, compared with the designs respectively shown in FIGS. 7a to 7d and FIGS. 8a to 8d.

For the arrangement in which the bumps 301 in each single functional network being arranged transversely (i.e., the Y direction) in the low-side power MOS region 300a, the design with the metal strips in the first metal layer being juxtaposed in the Y direction, the metal strips in the second metal layer in the X direction, the metal strips in the third metal layer in the Y direction and the metal strips in the fourth metal layer in the X direction in the low-side power connection region enables the package structure to have better electrical performance when compared to other designs.

This disclosure also provides a package structure. As shown in FIG. 2, the package structure includes the substrate 200 as defined above and a semiconductor die 300 flipped and mounted on the substrate 200.

As shown in FIGS. 2 and 3, the semiconductor die 300 has a front side facing toward the substrate 200, and a plurality of bumps 301 are provided on the front side of the semiconductor die 300. The semiconductor die 300 has a low-side power MOS region 300a aligned in position with the low-side power connection region of the substrate 200, and bumps in the low-side power MOS region 300a are connected to the metal strips in the topmost metal layer in the substrate 200 in the low-side power connection region.

The bumps 301 in the low-side power MOS region 300a of the semiconductor die 300 are arranged into a plurality of columns. Bumps 301 in each single column belong to the same functional network, and bumps 301 in adjacent two columns belong to different functional networks.

The semiconductor die 300 also has a high-side power MOS region 300b and a control circuit region 300c. Bumps 301 in the high-side power MOS region 300b and the low-side power MOS region 300a all have the same cross-sectional shape, which, however, is different from a cross-sectional shape of bumps (not shown) in the control circuit region 300c.

The bumps are shaped like posts. For example, the bumps 301 in the high-side power MOS region 300b and the low-side power MOS region 300a may all have an elliptic cross-section, while the bumps in the control circuit region 300c may all have a circular cross-section. The minor axis of the ellipse may be oriented in a direction defined by the columns of bumps. The major axis of the ellipse may range from 94 μm to 176 μm, and the minor axis thereof may range from 70 μm to 130 μm. The circular cross-section may have a diameter of 70 μm to 130 μm.

The package structure may further include a plastic encapsulation layer 400, which encapsulates the semiconductor die 300 and is filled between the semiconductor die 300 and the substrate 200. The plastic encapsulation layer 400 may be made of an epoxy plastic encapsulation material containing filler particles, which may be silica balls and may have a diameter less than or equal to 55 μm.

For example, the size of the package structure may be 3 mm×5 mm. The package structure may have 21 pins. The semiconductor die 300 may have a thickness of 0.17 mm to 0.21 mm. The plastic encapsulation layer 400 may have a thickness of 0.4 mm to 0.6 mm. The substrate 200 may have a thickness of 0.19 mm to 0.21 mm. However, the present disclosure is not so limited.

The foregoing description is merely that of several preferred embodiments of this disclosure and is not intended to limit the scope of the claims thereof in any way. Any person of skill in the art may make various possible variations and changes to the disclosed embodiments in light of the methodologies and teachings disclosed hereinabove, without departing from the spirit and scope of the invention. Accordingly, any and all such simple variations, equivalent alternatives and modifications made to the foregoing embodiments based on the essence of this disclosure without departing from the scope of the embodiments are intended to fall within the scope of protection of the disclosure.

What is claimed is:

1. A substrate, comprising a plurality of metal layers that are sequentially stacked from the top downward and electrically interconnected, and the metal layers being spaced apart by dielectric layers, the substrate having a low-side power connection region where metal strips in at least one of the metal layers extend in a direction different from a direction of extension of metal strips in another one of the metal layers extend.

2. The substrate of claim 1, wherein for each direction of extension, there are at least two of the metal layers, in which the metal strips extend in the specific direction of extension.

3. The substrate of claim 1, wherein the metal strips in any adjacent two of the metal layers extend in different directions.

4. The substrate of claim 1, wherein the low-side power connection region is aligned in position with a low-side power MOS region of the semiconductor die, and wherein bumps in the low-side power MOS region are connected to metal strips in a topmost one of the metal layers in the low-side power connection region.

5. The substrate of claim 4, wherein a plurality of metal strips are arranged in the topmost metal layer in the low-side power connection region, and wherein bumps in each single column in the low-side power MOS region of the semiconductor die are connected to a single one of the metal strips in the topmost metal layer.

6. The substrate of claim 5, wherein columns of bumps in the low-side power MOS region electrically connected to any respective adjacent two of the metal strips in the topmost metal layer in the low-side power connection region belong to different functional networks.

7. The substrate of claim 1, wherein the plurality of metal layers comprise a first metal layer, a second metal layer, a third metal layer and a fourth metal layer, which are sequentially stacked from the top downward and electrically interconnected, wherein in the low-side power connection region, the metal strips in two of the first, second, third and fourth metal layers extend in a first direction, and the metal strips in the remaining two metal layers extend in a second direction different from the first direction.

8. The substrate of claim 7, wherein the first direction is perpendicular to the second direction.

9. The substrate of claim 7, wherein the direction of extension of the metal strips in the first metal layer is same to the direction a plurality of columns of bumps extend.

10. The substrate of claim 7, comprising a solder mask on a surface thereof close to the fourth metal layer, the solder mask provided therein with a plurality of elongated openings, in which the fourth metal layer is partially exposed, wherein in the low-side power connection region, the direction of extension of the metal strips in the fourth metal layer is the same as a direction of extension of the elongated openings.

11. The substrate of claim 7, wherein in the low-side power connection region, the metal strips in the first metal layer extend in the first direction, the metal strips in the second metal layer extend in the second direction, the metal strips in the third metal layer extend in the first direction, and the metal strips in the fourth metal layer extend in the second direction.

12. A package structure, comprising the substrate of claim 1 and a semiconductor die flipped and mounted on the substrate.

13. The package structure of claim 12, wherein a front side of the semiconductor die faces toward the substrate and is provided thereon with a plurality of bumps, and wherein the semiconductor die has a low-side power MOS region, the low-side power MOS region is aligned in position with the low-side power connection region and provided therein with bumps connected to the metal strips in the topmost metal layer in the substrate in the low-side power connection region.

14. The package structure of claim 13, wherein the bumps in the low-side power MOS region of the semiconductor die are arranged into a plurality of columns, wherein bumps of each single one of the columns belong to the same functional network, and wherein bumps of any adjacent two of the columns belong to different functional networks.

15. The package structure of claim 13, wherein the semiconductor die further has a high-side power MOS region and a control circuit region, wherein bumps in the high-side power MOS region and the bumps in the low-side power MOS region have the same cross-sectional shape, and wherein the cross-sectional shape of the bumps in the high-side power MOS region or the cross-sectional shape of the bumps in the low-side power MOS region is different from a cross-sectional shape of bumps in the control circuit region.
